(19) United States
(12) Patent Application Publication
(10) Pub. No.: US 2011/0154823 A1
(43) Pub. Date: Jun. 30, 2011

(54) Energy regeneration system

(75) Inventors: Chu-Yang Chou, Taipel (TW); Way-Jone Hsiao, Taipei (TW); Yu-Hung Huang, Taipei County (TW)

(73) Assignee: Energy Spring Tech. Inc., Taipei County (TW)

(21) Appl. No.: 12/923,766

(22) Filed: Oct. 7, 2010

(30) Foreign Application Priority Data
Dec. 31, 2009 (TW) 098146097

(51) Int. Cl. H01M 12/00; H01L 35/30

(52) U.S. Cl. 60/682; 62/238.1

(57) ABSTRACT

An energy regeneration system comprises a heat pump, a bioreactor, a combustor, and a temperature difference electricity generation device. The heat pump is provided for thermally regulating the bioreactor and can be used for air-condition, dehumidification, refrigeration, chilling, heating and/or supplying hot water for bath. The bioreactor accommodates an organic material. The organic material is converted into a biomass fuel and other materials by microbial action. The chemical energy of the biomass fuel is converted into a heat energy by the combustor for actuating the temperature difference electricity generation device, thereby generating electrical energy.

### BACKGROUND OF THE INVENTION

1. Field of the Invention

The present invention relates to an energy regeneration system, and particularly to a system for converting biomass energy into heat energy, mechanical energy and/or electrical energy.

2. Description of the Related Art

U.S. Patent Publication No. 2008/0127657 disclosed a heat-pump-driven electricity generation device for generating electricity using a heat-pump-driven Stirling engine.

U.S. Pat. No. 6892522 disclosed an organic rankine cycle system combined with a vapor compression cycle system, for generating electricity using waste heat created by a gas turbine.

U.S. Patent Publication No. 2004/0093864 disclosed an electricity generation device using a Stirling engine.

### SUMMARY OF THE INVENTION

The present invention provides. an energy regeneration system, comprising: a heat pump, generating a hot source in thermal contact with a first working fluid and a cold source in thermal contact with a second working fluid; a bioreactor, generating a biomass fuel; a combustor, burning the biomass fuel to superheat a third working fluid, the third working fluid which is superheated being vaporized into a high temperature vapor; a temperature difference electricity generation device, comprising a hot end and a cold end, the hot end being in thermal contact with the high temperature vapor, the cold end being in thermal contact with a heat sink, so as to generate electricity; wherein the first working fluid and the second working fluid are used to thermally regulate the bioreactor.

According to a further aspect of the present invention, the bioreactor comprises a first reactor unit and/or a second reactor unit. The first reactor unit uses animals' excrements as a reaction substrate to generate a first biomass fuel. The second reactor unit uses animal/plant materials as a reaction substrate to generate a second biomass fuel. The first biomass fuel comprises methane, hydrogen and/or carbon monoxide, and the second biomass fuel comprises ethyl alcohol.

Animal/plant materials are referred to a portion of plants or animals, typically including kitchen waste, agricultural waste, forestry waste, animal husbandry waste and/or food industrial waste.

According to another aspect of the present invention, the temperature difference electricity generation device comprises a Stirling engine and a generator.

According to another aspect of the present invention, the system of the present invention further comprises a solar cell, a wind power generator and/or an electricity storage device. When an electrical energy is generated by a solar cell and/or a wind power generator, the electrical energy generated by the temperature difference electricity generation device is stored into the electricity storage device. The electricity storage device consists of one or more batteries.

By microbial action (for example, fermentation), organic materials (for example, animals' excrements, animal/plant materials, etc.) in the bioreactor are converted into biomass fuel for electricity generation. Such organic materials of animals' excrements and animal/plant materials generally are treated as waste. The present invention takes the organic materials as an energy source for use of energy regeneration. Thus, the requirements of petrochemical fuel or nature gas can be decreased, and emission of greenhouse gas can be reduced.

### BRIEF DESCRIPTION OF THE DRAWINGS

FIG. 1 shows an energy regeneration system according to the present invention.

### DESCRIPTION OF THE PREFERRED EMBODIMENTS

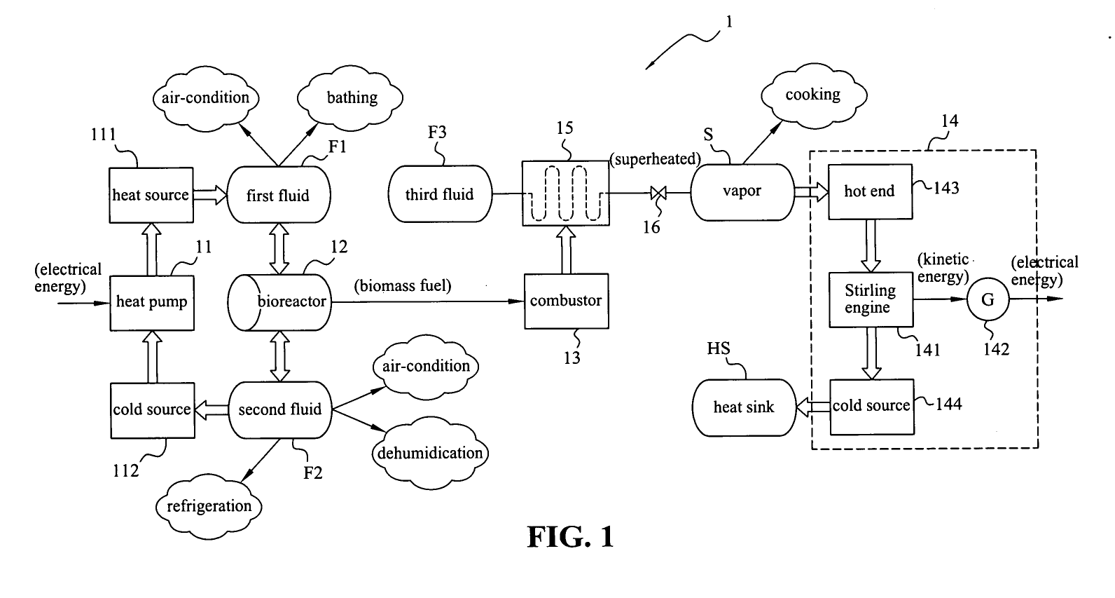

FIG. 1 schematically illustrates an energy regeneration system according to the present invention, the entire energy regeneration system designated with reference numeral 1.

The energy regeneration system 1 comprises a heat pump 11, a bioreactor 12, a combustor 13, and a temperature difference electricity generation device 14.

The heat pump 11 generates a heat source 111 and a cold source 112. The heat source 111 is in thermal contact with or exchanges heat with a first working fluid F1. The cold source 112 is in thermal contact with or exchanges heat with a second working fluid F2. The first fluid F1 and the second fluid F2 are water or glycol aqueous solution.

The bioreactor 12 is provided for generating biomass fuel. Preferably, the bioreactor 12 comprises a first reactor unit and a second reactor unit (not shown). The first reactor unit uses animals' excrements as a reaction substrate to generate first biomass fuel, comprising methane, hydrogen and carbon monoxide. The second reactor unit uses animal/plant materials as a reaction substrate to generate a second biomass fuel, comprising ethyl alcohol.

In the bioreactor 12, organic materials (for example, animals' excrements or animal/plant material waste, etc.) are converted into biomass fuel and other materials by microbial action. During this reaction, heat is generated. The reaction rate is substantially proportional directly to temperature. Therefore, thermal management of the bioreactor 12 is important and necessary. Advantageously, the bioreactor 12 is thermally regulated by the first working fluid F1 and the second working fluid F2, so as to control the reaction temperature and the reaction rate. For example, the reaction temperature is kept constant, or the reaction temperature is correspondingly increased or decreased according to the required reaction rate. Additionally, the first working fluid F1 can also be further used for air-condition, heating, and/or bath. The second working fluid F2 can also be further used for air-condition, dehumidification, refrigeration, and/or cooling. The first working fluid F1 and the second working fluid F2 can also provide cold and heat requirements for sauna or SPA, etc.

The biomass fuel generated by the bioreactor 12 is supplied to the combustor 13 and burned therein, so that a third working fluid F3 flowing through a heat exchanger 15 is heated to a superheat state. The third working fluid F3 which is superheated is vaporized into a high temperature vapor S. For example, the third working fluid F3 which is superheated is vaporized by a flash vaporizer 16.

It is known that a Stirling engine can directly convert a temperature difference into mechanical energy. In this embodiment, the temperature difference electricity generation device 14 comprises, but is not limited to, a Stirling engine 141 and a generator 142. Other known devices which can convert a temperature difference into mechanical energy or electrical energy directly or indirectly can also be used. In the case of the Stirling engine cycle, the hot end 143 of the Sterling engine 141 is in thermal contact with the high temperature vapor S. The cold end 144 of the Sterling engine 141 is in thermal contact with a heat sink HS, thereby operating the Sterling engine 141 to generate mechanical energy. The generator 142 converts the mechanical energy generated by the Sterling engine 141 into electrical energy. The cold end 144 may be ambient atmosphere and/or ground.

The vapor S can be used not only for generating electricity, but also a gas stove for cooking can be replaced with the vapor S.

Before the third fluid F3 is heated by the combustor, the third fluid F3 is preferably pre-heated by the heat source 111 and/or the bioreactor 12. For example, the third fluid F3 is pre-heated by the heat source 111 and the bioreactor 12 in sequence, or by the bioreactor 12 and the hot source 111 in sequence. The third fluid F3 can also be pre-heated by exchanging heat with the first fluid F1.

If the first fluid F1 and the third fluid F3 are all selected from the same working fluid (for example, water), the first fluid F1 can also be used as the third fluid F3.

The heat pump 11 absorbs heat not only from the second fluid F2 but also can absorb heat from the cold end 144 of the Sterling engine 141. In other words, the cold source 112 of the heat pump 11 can be used to increase the temperature difference between the hot end 143 and the cold end 144 of the Sterling engine 141.

The energy regeneration system according to the present invention further comprises a storage tank (not shown). The storage tank collects domestic wastewater, rainwater, and/or water generated by the bioreactor. If a large amount of water is stored in the storage tank, the storage tank may function as a heat sink which is thermally stable so as to thermally regulate the bioreactor and/or absorb heat from the cold end of the Sterling engine (i.e., functioning as the heat sink HS).

The energy regeneration system according to the present invention further comprises a solar cell, a wind power generator and/or an electricity storage device (not shown). The electricity storage device consists of one or more batteries (for example, polymeric lithium cells) for storing the electrical energy generated by the solar cell, the wind power generator and/or the temperature difference electricity generation device. In the case that the electricity requirement is satisfied by the solar cell and/or the wind power generator, the electrical energy generated by the temperature difference electricity generation device will be preferably stored in the electricity storage device, or the reaction of the bioreactor is stopped or the reaction rate thereof is reduced, by thermal regulation.

The electricity necessary for operation of the heat pump can also be supplied from at least one of the solar cell, the wind power generator, the electricity storage device, the temperature difference electricity generation device, and a power line of an electric power company.

The energy regeneration system according to the present invention can further comprises an automatic transfer switch (ATS) for selectively or controllably connecting a power requirement terminal (a load) to the power supply system of the electric power company or the energy regeneration system. In the case that the power requirement terminal is connected to the power supply system of the electric power company, the electrical energy generated by the energy regeneration system can be stored in the electricity storage device. For example, in the case that power supply of the electric power company is interrupted, the automatic transfer switch automatically connects the power requirement terminal to the energy regeneration system so as to prevent power supply to the power requirement terminal from interruption.

While the present invention has been exemplarily described with reference to the preferred embodiment, it should be understood that various changes and modifications could be made by a skilled person within the spirit and scope of the inventive concepts described. Accordingly, it is intended that the present invention shall not be limited to the disclosed embodiment, but have the full scope permitted by the language of the following claims.

What is claimed is:

1. An energy regeneration system, comprising:
a heat pump, generating a heat source and a cold source, the hot source being in thermal contact with a first working fluid, and the cold source being in thermal contact with a second working fluid;
a bioreactor, generating a biomass fuel and a heat energy;
a combustor, burning the biomass fuel to superheat a third working fluid, the third working fluid which is superheated being vaporized into a high temperature vapor;
a temperature difference electricity generation device, comprising a hot end and a cold end, the hot end being in thermal contact with the high temperature vapor, the cold end being in thermal contact with a heat sink, so as to generate electricity;
wherein the first working fluid and the second working fluid are used to thermally regulate the bioreactor.

2. The system of claim 1, wherein the first working fluid is further used for air-condition, bath and/or heating, and the second working fluid is further used for air-condition, dehumidification, refrigeration and/or cooling.

3. The system of claim 1, wherein the bioreactor comprises a first reactor unit and/or a second reactor unit, the first reactor unit using animals' excrements as a reaction substrate to generate a first biomass fuel, and the second reactor unit using animal/plant materials as a reaction substrate to generate a second biomass fuel.

4. The system of claim 3, wherein the first biomass fuel comprises methane, hydrogen and/or carbon monoxide, and the second biomass fuel comprises methyl alcohol and ethyl alcohol.

5. The system of claim 1, wherein the third working fluid is pre-heated by the heat source and/or the bioreactor prior to being superheated by the combustor.

6. The system of claim 5, wherein the third working fluid is pre-heated by the heat source and the bioreactor in sequence prior to being superheated by the combustor.

7. The system of claim 5, wherein the third working fluid is pre-heated by the bioreactor and the heat source in sequence prior to being superheated by the combustor.

8. The system of claim 1, wherein the third fluid which is superheated is vaporized into a high temperature vapor via a flash vaporizer.

9. The system of claim 1, wherein the heat sink is ambient atmosphere and/or ground.

10. The system of claim 1, wherein the cold source functions as the heat sink.

11. The system of claim 1, wherein a part of the high temperature vapor is used for cooking.

12. The system of claim 1, wherein the first fluid, the second fluid, and the third fluid are water or aqueous solution.

13. The system of claim 1, wherein the temperature difference electricity generation device comprises a Stirling engine and a generator.

14. The system of claim 1, further comprising a storage tank for storing domestic wastewater, wastewater created by the bioreactor and/or rainwater.

15. The system of claim 14, wherein the storage tank functions as the heat sink.

16. The system of claim 14, wherein the storage tank is used for thermally regulating the bioreactor.

17. The system of claim 1, further comprising a solar cell, a wind power generator and/or an electricity storage device.

18. The system of claim 17, wherein the electricity storage device consists of one or more batteries.

19. The system of claim 1, further comprising an automatic transfer switch (ATS) for selectively connecting a power requirement terminal to a power line of an electric power company or the energy regeneration system.
